(19) United States
(12) Patent Application Publication
(10) Pub. No.: US 2024/0006160 A1
(43) Pub. Date: Jan. 4, 2024

(54) SUBSTRATE PROCESSING APPARATUS

(71) Applicant: SEMES CO., LTD., Chungcheongnam-do (KR)

(72) Inventors: Kwangryul KIM, Suwon-si (KR); Yunsang KIM, Seongnam-si (KR)

(21) Appl. No.: 18/142,442

(22) Filed: May 2, 2023

(30) Foreign Application Priority Data
Jul. 4, 2022 (KR) 10-2022-0082114

(51) Int. Cl. H01J 37/32; B23K 26/352

(52) U.S. Cl. CPC H01J 37/32449; H01J 37/32568; H01J 37/32082; B23K 26/352; H01J 2237/002; H01J 2237/334

(57) ABSTRACT

Provided is a substrate processing apparatus including a chamber including a processing space; a support table provided within the processing space of the chamber and configured to support a substrate; a dielectric plate covering an opening in an upper wall of the chamber; a transparent electrode provided on the dielectric plate; a laser supply head configured to supply a laser beam toward the substrate supported on the support table via the transparent electrode and the dielectric plate; and a cooling device configured to cool the transparent electrode by injecting a cooling gas toward the transparent electrode.

### CROSS-REFERENCE TO RELATED APPLICATION

This application is based on and claims priority under 35 U.S.C. § 119 to Korean Patent Application No. 10-2022-0082114, filed on Jul. 4, 2022, in the Korean Intellectual Property Office, the disclosure of which is incorporated by reference herein in its entirety.

### BACKGROUND

### 1. Field

The disclosure relates to a substrate processing apparatus.

### 2. Description of the Related Art

In general, in order to manufacture a semiconductor device, a series of semiconductor processes, such as deposition, etching, and cleaning may be performed on a substrate. In the case of some semiconductor processes, for example, a heat source is used to quickly heat a substrate to a predetermined temperature when performing a process such as deposition or etching on a substrate using plasma. A heat source for heating the substrate may be an electric resistance heater, a light source, and the like.

However, when the substrate is heated using the heat source, other peripheral components are unintentionally heated and may deteriorate.

### SUMMARY

Provided is a substrate processing apparatus.

Additional aspects will be set forth in part in the description which follows and, in part, will be apparent from the description, or may be learned by practice of the presented embodiments of the disclosure.

According to an aspect of the disclosure, a substrate processing apparatus includes a chamber including a processing space; a support table provided within the processing space of the chamber and configured to support a substrate; a dielectric plate covering an opening in an upper wall of the chamber; a transparent electrode provided on the dielectric plate; a laser supply head configured to supply a laser beam toward the substrate supported on the support table via the transparent electrode and the dielectric plate; and a cooling device configured to cool the transparent electrode by injecting a cooling gas toward the transparent electrode.

In embodiments, the cooling device includes a first gas injection block including at least one first injector configured to inject the cooling gas; and a first suction block including at least one first suction port configured to suck the cooling gas, and disposed to face the first gas injection block in a first direction parallel to an upper surface of the transparent electrode.

In embodiments, the first gas injection block is configured to inject the cooling gas in a direction parallel to the upper surface of the transparent electrode.

In embodiments, the first gas injection block is configured to inject the cooling gas in an inclined direction to the upper surface of the transparent electrode.

In embodiments, the first gas injection block includes a plurality of first injection ports spaced apart from each other along a second direction parallel to the upper surface of the transparent electrode and perpendicular to the first direction.

In embodiments, a length of the at least one first suction ports in the second direction is greater than a length of each of the plurality of first injection ports in the second direction.

In embodiments, the cooling device is further configured to form an airflow of the cooling gas flowing in one direction along the upper surface of the transparent electrode between the first gas injection block and the first suction block.

In embodiments, the cooling device further includes a second gas injection block including at least one second injection ports configured to inject the cooling gas; and a second suction block including at least one second suction port configured to suck the cooling gas and disposed to face the second gas injection block in a second direction parallel to an upper surface of the transparent electrode and perpendicular to the first direction, and the cooling device is configured to form an airflow of the cooling gas flowing in the second direction along the upper surface of the transparent electrode between the second gas injection block and the second suction block.

In embodiments, the substrate processing apparatus further includes flow guide blocks spaced apart from each other in a second direction perpendicular to the first direction with the transparent electrode therebetween, wherein the flow guide blocks extend in the first direction between the first gas injection block and the first suction block to guide the flow of the cooling gas in the first direction.

In embodiments, the substrate processing apparatus further includes an actuator configured to move the first gas injection block, wherein the actuator is configured to move the first gas injection block to adjust an injection direction of the cooling gas injected from the first gas injection block.

In embodiments, the substrate processing apparatus further includes a third gas injection block spaced apart from the first suction block in the first direction with the transparent electrode therebetween, wherein the first gas injection block is configured to inject the cooling gas in a direction parallel to an upper surface of the transparent electrode, and the third gas injection block is configured to inject the cooling gas in an inclined direction to the upper surface of the transparent electrode.

In embodiments, the dielectric plate includes quartz, and the transparent electrode includes indium tin oxide.

In embodiments, the cooling gas includes at least one of clean dry air and nitrogen gas.

In embodiments, the substrate processing apparatus further includes a gas supplier configured to supply a process gas to the processing space; a first power supply configured to supply first power to the transparent electrode; and a second power supply configured to supply second power to an internal electrode plate of the support table.

According to another aspect of the disclosure, a substrate processing apparatus includes a chamber including a processing space; a support table provided within the processing space of the chamber and configured to support a substrate; a gas supplier configured to supply a process gas to the processing space; a dielectric plate covering an opening in an upper wall of the chamber; a transparent electrode provided outside the chamber and provided on the dielectric plate; a first power supply configured to supply first power to the transparent electrode; a second power supply configured to supply second power to an internal electrode plate of the support table; a laser supply head configured to supply a laser beam toward the substrate on the support table through the transparent electrode and the dielectric plate; and a cooling device configured to cool the transparent electrode by forming an airflow of a cooling gas flowing in one direction along an upper surface of the transparent electrode.

In embodiments, the cooling device includes a first gas injection block including a plurality of first injection ports configured to inject the cooling gas; and a first suction block including a first suction port configured to suck the cooling gas and spaced apart from the first gas injection block in a first direction from a first edge to a second edge of the transparent electrode, wherein the plurality of first injection ports are spaced apart from each other in a second direction perpendicular to the first direction, and the first suction port faces each of the plurality of first injection ports in the first direction.

In embodiments, the first gas injection block and the first suction block are spaced apart from each other in the first direction with the transparent electrode therebetween, and a length of the first gas injection block in the second direction and a length of the suction block in the second direction are each greater than a length of the transparent electrode in the second direction.

In embodiments, the first gas injection block and the first suction block are arranged so as not to overlap the transparent electrode in a vertical direction perpendicular to the upper surface of the transparent electrode.

In embodiments, the cooling device is configured to supply the cooling gas toward the transparent electrode to cool the transparent electrode while the laser supply head supplies the laser beam toward the substrate.

According to another aspect of the disclosure, a substrate processing apparatus includes a chamber including a processing space in which plasma is generated; a support table provided within the processing space of the chamber and configured to support a substrate; a gas supplier configured to supply a process gas to the processing space; a dielectric plate covering an opening in an upper wall of the chamber; a transparent electrode provided outside the chamber and provided on the dielectric plate; a first power supply configured to supply first power to the transparent electrode; a second power supply configured to supply second power to an internal electrode plate of the support table; a laser supply head configured to supply a laser beam toward the substrate on the support table through the transparent electrode and the dielectric plate; and a cooling device including a first gas injection block having a plurality of first injection ports configured to inject a cooling gas toward the transparent electrode and a first suction block having a first suction port configured to suck the cooling gas, wherein the first gas injection block and the first suction block are spaced apart from each other in a first direction parallel to an upper surface of the transparent electrode with the transparent electrode therebetween, wherein the first gas injection block is disposed near a first edge of the transparent electrode and extends from one end to the other end of the first edge of the transparent electrode, the first suction block is disposed near a second edge opposite to the first edge of the transparent electrode and extends from one end to the other end of the second edge of the transparent electrode, the first suction port faces each of the plurality of first injection ports in the first direction, a length in a vertical direction perpendicular to the upper surface of the transparent electrode of the first suction port is greater than a length in a vertical direction of each of the plurality of first injection ports, and the cooling device is configured to form an airflow of the cooling gas flowing in one direction along the upper surface of the transparent electrode between the first gas injection block and the first suction block.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a configuration diagram illustrating a substrate processing apparatus according to embodiments.

FIG. 2 is a plan view showing some configurations of the substrate processing apparatus of FIG. 1.

FIG. 3 is a side view illustrating an injection surface of a first gas injection block according to embodiments.

FIG. 4 is a side view showing a suction surface of a first suction block according to embodiments.

FIG. 5 is a configuration diagram showing a portion of a substrate processing apparatus including a cooling device according to embodiments.

FIG. 6 is a configuration diagram showing a portion of a substrate processing apparatus including a cooling device according to embodiments.

FIG. 7 is a configuration diagram showing a portion of a substrate processing apparatus including a cooling device according to embodiments.

FIGS. 8A and 8B are configuration diagrams showing portions of a substrate processing apparatus including a cooling device according to embodiments.

FIG. 9 is a configuration diagram showing a portion of a substrate processing apparatus including a cooling device according to embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments of the technical idea of the disclosure will be described in detail with reference to the accompanying drawings. The same reference numerals are used for the same components in the drawings, and descriptions already given for them are omitted.

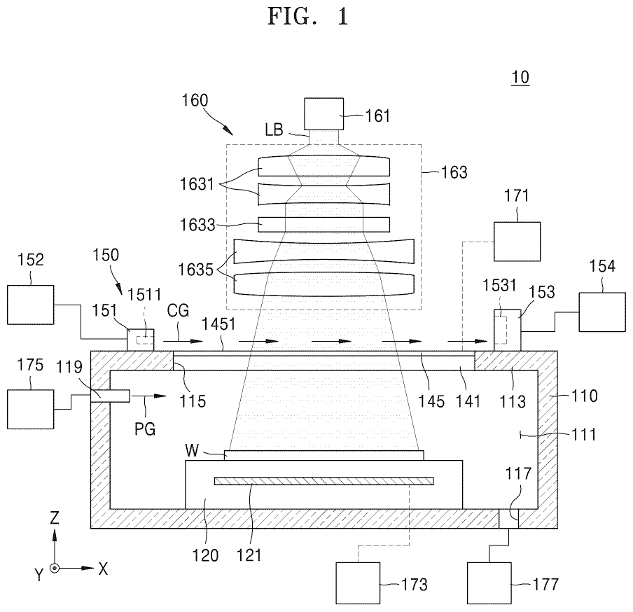

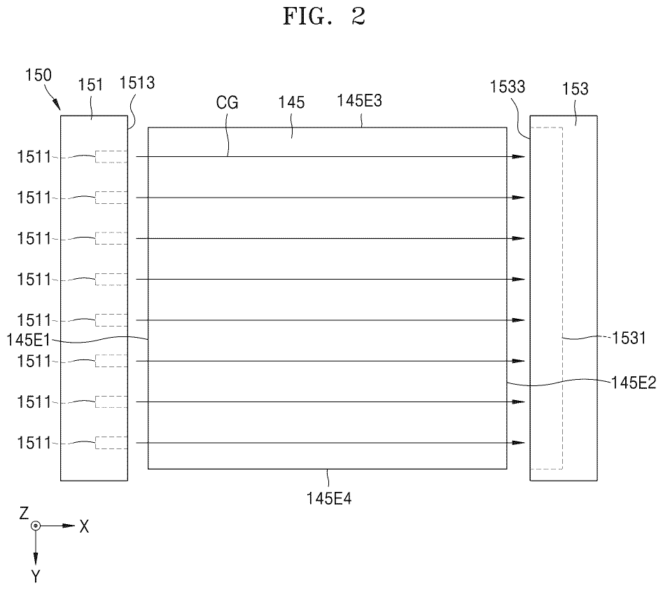

FIG. 1 is a configuration diagram illustrating a substrate processing apparatus 10 according to embodiments. FIG. 2 is a plan view showing some configurations of the substrate processing apparatus 10 of FIG. 1.

Referring to FIGS. 1 and 2, a substrate processing apparatus 10 may include a chamber 110, a support table 120, a dielectric plate 141, a transparent electrode 145, a cooling device 150, a laser supply head 160, a process gas supplier 175, a first power supply 171, and a second power supply 173.

The chamber 110 may provide a processing space 111. The processing space 111 of the chamber 110 may be provided as a space in which the substrate W is processed, and an access gate for accessing and exiting the substrate W may be provided at one side of the chamber 110. The processing space 111 of the chamber 110 may be provided as a space that may be sealed with respect to an external space of the chamber 110. The chamber 110 may have a cylindrical shape, an elliptical column shape, or a polygonal column shape. An opening 115 penetrating an upper wall 113 of the chamber 110 may be provided in the upper wall 113 of the chamber 110. When viewed from a plan view, the shape of the opening 115 of the chamber 110 may be a polygon such as a square or a circle.

An exhaust port 117 may be formed in the lower portion of the chamber 110. An exhaust device 177 may be connected to the exhaust port 117 of the chamber 110 through a pipe, and may be configured to exhaust materials in the chamber 110 to the outside of the chamber 110. The exhaust device 177 may include a vacuum pump. The exhaust device 177 may function to control the internal pressure of the processing space 111 of the chamber 110 by exhausting materials in the processing space 111 of the chamber 110, and may also function to discharge reaction by-products generated during processing of the substrate W to the outside of the chamber 110.

A gas supply port 119 for injecting process gas PG may be disposed at one side of the chamber 110. The process gas supplier 175 may be connected to the gas supply port 119 of the chamber 110 through a pipe, and may be configured to supply the process gas PG to the processing space 111 of the chamber 110 through the supply port 119 of the chamber 110. The process gas supplier 175 may include at least one gas source for storing and supplying various process gases PG. For example, the process gas PG may include a gas for generating plasma, a gas that reacts with the substrate W to be processed (e.g., an etching source gas or a deposition source gas), a purge gas, and the like.

The support table 120 may be provided in the processing space 111 of the chamber 110 and configured to support the substrate W. The substrate W may be placed on a main surface of the support table 120. The substrate W may include, for example, a semiconductor wafer. In embodiments, the support table 120 may include an electrostatic chuck configured to support the substrate W with electrostatic force or a vacuum chuck configured to selectively vacuum adsorb the substrate W.

The dielectric plate 141 may be coupled to the chamber 110 to cover the opening 115 of the chamber 110. For example, the dielectric plate 141 may be inserted into and fixed to the opening 115 of the chamber 110. When viewed from a plan view, the shape of the dielectric plate 141 may correspond to the shape of the opening 115 of the chamber 110. For example, the dielectric plate 141 may have a rectangular shape in plan view. The dielectric plate 141 may block the flow of gas through the opening 115 of the chamber 110 by closing the opening 115 of the chamber 110. The dielectric plate 141 may be made of a material that transmits light to a laser beam LB. For example, the transmittance of the laser beam LB of the dielectric plate 141 may be 75% or more, 80% or more, 85% or more, 90% or more, or 95% or more. In embodiments, the dielectric plate 141 may include at least one of quartz and aluminum nitride.

The transparent electrode 145 may be disposed on the upper surface of the dielectric plate 141. The transparent electrode 145 may be provided in an external space of the chamber 110 and may not be exposed to the processing space 111 of the chamber 110. The transparent electrode 145 extends along the upper surface of the dielectric plate 141 and may cover the upper surface of the dielectric plate 141. When viewed from a plan view, the shape of the transparent electrode 145 may be the same as that of the dielectric plate 141. For example, the transparent electrode 145 may have a rectangular shape in a plan view. The transparent electrode 145 may be a thin film having a thickness between several tens of nanometers and several thousand nanometers. In embodiments, the thickness of the transparent electrode 145 may be between about 300 nm and about 900 nm. An upper surface 1451 of the transparent electrode 145 may be substantially flat. Hereinafter, a horizontal direction (e.g., an X direction and/or a Y direction) may be defined as a direction parallel to the upper surface 1451 of the transparent electrode 145, and a vertical direction (e.g., a Z direction) may be defined as a direction perpendicular to the upper surface 1451 of the transparent electrode 145.

The transparent electrode 145 may include a conductive material and may be configured to receive externally supplied power. In addition, the transparent electrode 145 may be made of a material that transmits light to the laser beam LB. For example, the transmittance of the laser beam LB of the transparent electrode 145 may be 75% or more, 80% or more, 85% or more, 90% or more, or 95% or more. In embodiments, the transparent electrode 145 may include at least one of indium tin oxide (ITO), indium zinc oxide (IZO), tin oxide (SnO₂), and zinc oxide (ZnO).

The first power supply 171 may be configured to supply first power to the transparent electrode 145. For example, the first power supply 171 may be configured to supply radio frequency (RF) power, a reference potential (e.g., ground voltage), or bias power to the transparent electrode 145. The second power supply 173 may be configured to supply second power to an internal electrode plate 121 of the support table 120. For example, the second power supply 173 may be configured to supply RF power, a reference potential (e.g., ground voltage), or bias power to the internal electrode plate 121 of the support table 120.

In embodiments, the substrate processing device 10 may correspond to a capacitively coupled plasma device. Plasma may be generated from the process gas PG supplied to the processing space 111 by forming an electric field between the transparent electrode 145 and the internal electrode plate 121 of the support table 120. For example, to form an electric field for generating plasma in the processing space 111, the first power supply 171 may provide a reference potential to the transparent electrode 145 and the second power supply 173 may provide RF power to the internal electrode plate 121 of the support table 120. Alternatively, in order to form an electric field for generating plasma in the processing space 111, the first power supply 171 may provide RF power to the transparent electrode 145 and the second power supply 173 may provide a reference potential to the internal electrode plate 121 of the support table 120. The substrate processing apparatus 10 may be configured to perform an etching process, a cleaning process, a deposition process, and the like on the substrate W using plasma generated in the processing space 111. In embodiments, the substrate processing apparatus 10 may be configured to perform atomic layer etching (ALE) or atomic layer deposition (ALD) on the substrate W.

The laser supply head 160 may supply the laser beam LB toward the substrate W. The laser supply head 160 may be disposed outside the chamber 110 and supply the laser beam LB to the substrate W through the transparent electrode 145 and the dielectric plate 141.

The laser supply head 160 may include a light source 161 and an optical system 163. The light source 161 may generate and output a laser beam LB. The light source 161 may include one light source or a plurality of light sources. The optical system 163 may include at least one collimating optical system 1631, a homogenizing optical system 1633, and an imaging optical system 1635. The optical system 163 may be configured to adjust the shape and/or size of the laser beam LB. For example, the optical system 163 may adjust the shape and/or size of the laser beam LB to be substantially the same as or similar to the shape and/or size of the substrate W.

The laser supply head 160 may supply a laser beam LB toward the substrate W to perform heat treatment on the substrate W. The laser supply head 160 may be configured to output a laser beam LB having characteristics suitable for heat treating the substrate W. For example, the wavelength, pulse width, and power of the laser beam LB output from the laser supply head 160 may be adjusted depending on the material and thickness of the substrate W, the target heating temperature of the substrate W, and the like. In embodiments, the wavelength of the laser beam LB may be between about 500 nm and about 1200 nm, and the power of the laser beam LB may be between about 10 W and about 700 W. In embodiments, when the substrate processing apparatus 10 is configured to perform an ALE process, the laser supply head 160 may rapidly heat the substrate W by supplying the laser beam LB to the entire area of the substrate W, and the material layer to be etched on the substrate W may be volatilized and removed by rapid heating of the substrate W.

The cooling device 150 may be provided outside the chamber 110 and may be configured to cool the transparent electrode 145 by injecting a cooling gas CG to the transparent electrode 145. The cooling device 150 may be configured to cool the transparent electrode 145 by forming an air flow of cooling gas CG flowing along the upper surface 1451 of the transparent electrode 145 on the upper surface 1451 of the transparent electrode 145. For example, the cooling gas CG may include clean dry air and/or nitrogen gas. As mentioned above, because the opening 115 of the upper wall 113 of the chamber 110 is closed by the dielectric plate 141, the cooling gas CG does not flow into the processing space 111. In embodiments, cooling of the transparent electrode 145 using the cooling device 150 may be performed while the laser beam LB is heating the substrate W. In embodiments, cooling of the transparent electrode 145 using the cooling device 150 may be performed before heat treatment of the substrate W using the laser beam LB starts. In embodiments, cooling of the transparent electrode 145 using the cooling device 150 may be performed after heat treatment of the substrate W using the laser beam LB is completed.

The cooling device 150 may include a first gas injection block 151, a cooling gas supplier 152, a first suction block 153, and an exhaust pump 154.

The first gas injection block 151 may be configured to inject the cooling gas CG toward the transparent electrode 145. The first gas injection block 151 may include at least one first injection port 1511 configured to inject the cooling gas CG. The first injection port 1511 may be a hole provided in the first gas injection block 151. A injection surface 1513 of the first gas injection block 151 provided with the first injection port 1511 may be disposed to face the transparent electrode 145. The first gas injection block 151 may be disposed on the upper wall 113 of the chamber 110, and may be disposed so as not to overlap the optical path of the laser beam LB in a vertical direction (e.g., Z direction). For example, the first gas injection block 151 may be disposed so as not to overlap the transparent electrode 145 in a vertical direction (e.g., Z direction).

In embodiments, the first gas injection block 151 may be configured to inject the cooling gas CG in a direction parallel to the upper surface 1451 of the transparent electrode 145. In this case, the injection direction of the first gas injection block 151 may be determined by the extending direction of the first injection port 1511. For example, the first injection port 1511 may extend from the injection surface 1513 toward the inside in a direction parallel to the upper surface 1451 of the transparent electrode 145 so that the cooling gas CG is injected in a direction parallel to the upper surface 1451 of the transparent electrode 145.

The cooling gas supplier 152 is connected to the first injection port 1511 of the first gas injection block 151 through a supply line, and may supply the cooling gas CG to the first gas injection block 151. The cooling gas supplier 152 may include a cooling gas source for storing and supplying a cooling gas CG, a temperature controller (e.g., a heater and/or a chiller) configured to control the temperature of the cooling gas CG, a temperature sensor configured to sense a temperature of the cooling gas CG, and a flow meter for controlling the flow rate and velocity of the cooling gas CG.

The first suction block 153 may be configured to suck the cooling gas CG injected from the first gas injection block 151. The first suction block 153 may include at least one first suction port 1531 configured to suck the cooling gas CG. The first suction port 1531 may be a hole provided in the first suction block 153. The first suction block 153 may be disposed on the upper wall 113 of the chamber 110 and may be disposed so as not to overlap the light path of the laser beam LB in a vertical direction (e.g., Z direction). For example, the first suction block 153 may be disposed so as not to overlap the transparent electrode 145 in a vertical direction (e.g., Z direction).

The exhaust pump 154 may be connected to the first suction port 1531 of the first suction block 153 through a suction line, and may exhaust the cooling gas CG sucked into the first suction port 1531. The exhaust pump 154 may adjust the suction force acting on the first suction port 1531 so that the flow rate of the cooling gas CG flowing over the transparent electrode 145 is adjusted.

In embodiments, the first gas injection block 151 and the first suction block 153 may face each other in a first direction (e.g., the X direction) parallel to the upper surface 1451 of the transparent electrode 145, and may be spaced apart from each other in the first direction (e.g., the X direction) with the transparent electrode 145 therebetween. For example, the first gas injection block 151 may be disposed near a first edge 145E1 of the transparent electrode 145, and the first suction block 153 may be disposed near a second edge 145E2 opposite to the first edge 145E1 of the transparent electrode 145. In this case, the injection surface 1513 or the first injection port 1511 of the first gas injection block 151 may face a suction surface 1533 or the first suction port 1531 of the first suction block 153 in the first direction (e.g., the X direction). As the first gas injection block 151 and the first suction block 153 are disposed to face each other in the first direction (e.g., the X direction), an air flow of the cooling gas CG uniformly flowing in the first direction (e.g., the X direction) along the upper surface 1451 of the transparent electrode 145 may be formed between the first gas injection block 151 and the first suction block 153. Because a uniform air flow of the cooling gas CG is formed on the transparent electrode 145, cooling of the transparent electrode 145 using the cooling gas G may be uniformly performed over the entire transparent electrode 145.

In embodiments, the first gas injection block 151 and the first suction block 153 may have a bar shape extending in the second direction (e.g., the Y direction) parallel to the upper surface 1451 of the transparent electrode 145 and perpendicular to the first direction (e.g., the X direction). The second direction (e.g., the Y direction) may be a direction parallel to the first edge 145E1 or the second edge 145E2 of the transparent electrode 145. A length of the first gas injection block 151 along the second direction (e.g., the Y direction) and a length of the first suction block 153 along the second direction (e.g., the Y direction) may be equal to or greater than a length (or maximum width) of the transparent electrode 145 in the second direction (e.g., the Y direction), respectively.

TABLE 1

| | power | | absorption | |
|---|---|---|---|---|
| wavelength | of the | reflectance | rate of | |
| of the laser | laser | of dielectric | transparent | laser |
| beam | beam | plate | electrode | transmittance |
| (nm) | (W) | (quartz) (%) | (ITO) (%) | (%) |
| 527 | 100 | 8.0 | 14.6 | 77.4 |
| 808 | 250 | 8.0 | 12.0 | 80.0 |
| 980 | 500 | 8.0 | 8.3 | 83.7 |
| 1070 | 20 | 8.0 | 10.1 | 81.9 |

Table 1 shows the result of detecting the laser transmittance of the coupling structure and the absorption rate of the transparent electrode 145 after irradiating the laser beam LB to the coupling structure of the transparent electrode 145 and the dielectric plate 141. The laser transmittance of the coupling structure may be measured through a power meter, and the absorptivity of the transparent electrode 145 may be obtained using a result measured by a power meter. In Table 1, the transparent electrode 145 is formed of an ITO film having a thickness of approximately 600 nm, and the dielectric plate 141 is formed of quartz. As shown in Table 1, it may be confirmed that the transparent electrode 145 has an absorption rate of approximately 8% to 15% depending on the wavelength and power of the laser beam LB. That is, while the transparent electrode 145 functions as an electrode for plasma generation and simultaneously transmits the laser beam LB so that the substrate W may be heated, the laser beam LB is absorbed by the transparent electrode 145 and the temperature of the laser beam LB rises. As the transparent electrode 145 is heated by the laser beam LB, there is an issue that the transparent electrode 145 is thermally damaged.

However, according to embodiments, by cooling the transparent electrode 145, the cooling device 150 may maintain the temperature of the transparent electrode 145 within a predetermined allowable range even while the laser beam LB is being irradiated, and may prevent deterioration of the transparent electrode 145 due to thermal damage of the transparent electrode 145. Accordingly, reliability of the substrate processing apparatus 10 including the transparent electrode 145 may be improved.

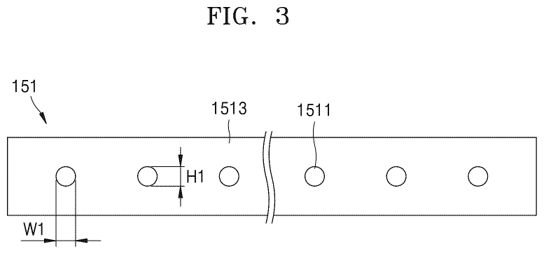

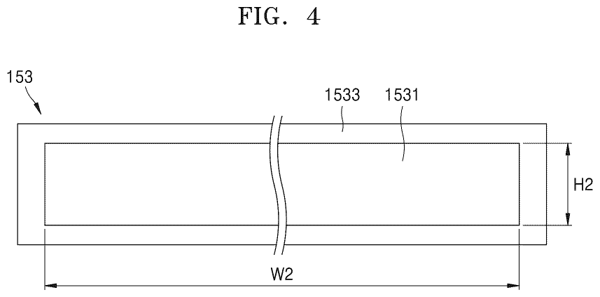

FIG. 3 is a side view illustrating an injection surface 1513 of a first gas injection block 151 according to embodiments. FIG. 4 is a side view showing a suction surface 1533 of a first suction block 153 according to embodiments.

Referring to FIGS. 1 to 4, the first gas injection block 151 may include a plurality of first injection ports 1511 spaced apart from each other. The plurality of first injection ports 1511 may be spaced apart from each other in the second direction (e.g., the Y direction). As the cooling gas CG is injected through the plurality of first injection ports 1511, the speed of the cooling gas CG may increase and the uniformity of the flow of the cooling gas CG may be improved. In embodiments, the plurality of first injection ports 1511 may have the same dimensions (e.g., diameters). In embodiments, the plurality of first injection ports 1511 may be spaced apart at equal intervals. In FIG. 2, the first gas injection block 151 is illustrated as including eight first injection ports 1511, but the number of first injection ports 1511 is not limited thereto. For example, the first gas injection block 151 may include several to hundreds of first injection ports 1511.

The first suction block 153 may include a single first suction port 1531. The single first suction port 1531 may face each of the plurality of first injection ports 1511 in the first direction. The single first suction port 1531 may extend from one end to the other end of the second edge 145E2 of the transparent electrode 145 along the second edge 145E2 of the transparent electrode 145. The single first suction port 1531 has a slit shape, and a length W2 of the single first suction port 1531 in the horizontal direction may be greater than a length H2 of the single first suction port 1531 in the vertical direction. In addition, the length W2 of the single first suction port 1531 in the horizontal direction may be greater than a length W1 of each of the plurality of first nozzles 1511 in the horizontal direction, and the length H2 of the single first suction port 1531 in the vertical direction may be greater than a length H1 of each of the plurality of first injection ports 1511 in the vertical direction. The area of the single first suction port 1531 may be greater than the total area of the plurality of first injection ports 1511. As the single first suction port 1531 of the first suction block 153 is formed in a large area, the exhaust speed of the cooling gas CG through the first suction block 153 may be increased.

In embodiments, the first suction block 153 may include a plurality of first suction ports 1531 spaced apart from each other in the second direction. In this case, a size of each of the plurality of first suction ports 1531 may be greater than a corresponding size of each of the plurality of first injection ports 1511. For example, the length H2 of each of the plurality of first suction ports 1531 in the vertical direction is greater than the length H1 of each of the plurality of first injection ports 1511 in the vertical direction, and the length W2 of each of the plurality of first inlets 1531 in the horizontal direction may be greater than the length W1 of each of the plurality of first spray holes 1511 in the horizontal direction. In addition, the total area of the plurality of first suction ports 1531 included in the first suction block 153 may be greater than the total area of the plurality of first injection ports 1511.

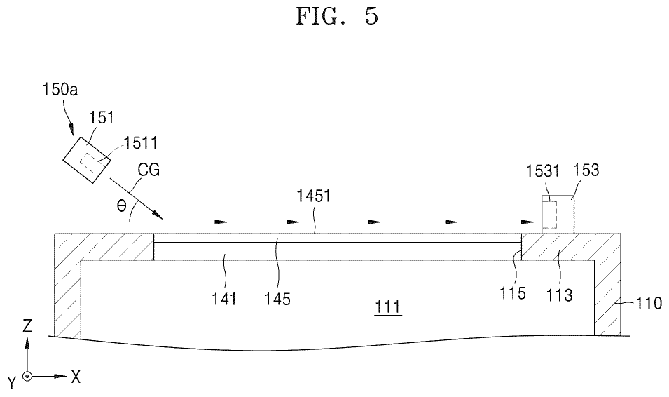

FIG. 5 is a configuration diagram showing a portion of a substrate processing apparatus including a cooling device 150a according to embodiments. Hereinafter, a substrate processing apparatus including the cooling device 150a of FIG. 5 is described, focusing on differences from the substrate processing apparatus 10 previously described with reference to FIGS. 1 to 4.

Referring to FIG. 5, a first gas injection block 151 may be configured to inject the cooling gas CG in an inclined direction with respect to an upper surface 1451 of a transparent electrode 145. For example, the first gas injection block 151 may inject a cooling gas CG with respect to the upper surface 1451 of the transparent electrode 145 at an inclination angle θ between about 1 degree and about 60 degrees. The cooling gas CG injected from the first gas injection block 151 may flow toward a first edge 145E1 of the transparent electrode 145 and then may flow in a first direction (e.g., an X direction) along the upper surface 1451 of the transparent electrode 145 and be sucked into the first suction port 1531 of the first suction block 153.

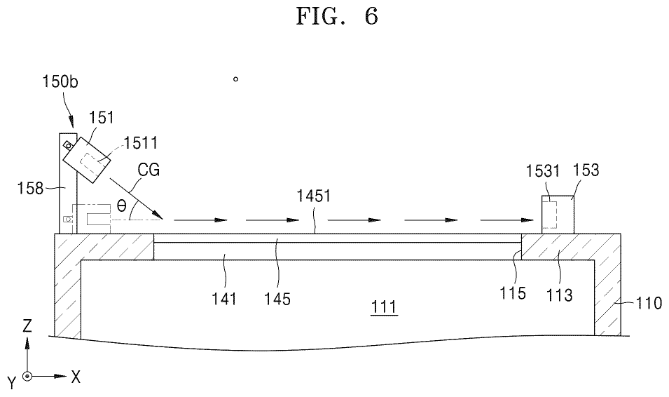

FIG. 6 is a configuration diagram showing a portion of a substrate processing apparatus including a cooling device 150b according to embodiments. Hereinafter, a substrate processing apparatus including the cooling apparatus 150b of FIG. 6 is described, focusing on differences from the substrate processing apparatus 10 previously described with reference to FIGS. 1 to 4.

Referring to FIG. 6, the first gas injection block 151 may be configured to be movable. The first gas injection block 151 may move so as to adjust the injection direction of the cooling gas CG. The first gas injection block 151 may be configured to move so that an inclination angle θ formed between the injection direction of the cooling gas CG and an upper surface 1451 of the transparent electrode 145 is adjusted. For example, the first gas injection block 151 may be configured to move in a horizontal direction (e.g., an X direction and/or a Y direction) and/or a vertical direction (e.g., a Z direction). For example, the first gas injection block 151 may be configured to rotate in a direction parallel to the first edge 145E1 of the transparent electrode 145 (e.g., the Y direction) as a rotation axis. The cooling device 150b may include an actuator 158 configured to move the first gas injection block 151. The actuator 158 may control horizontal movement, vertical movement, and/or rotational movement of the first gas injection block 151. The actuator 158 may linearly move or rotate the first gas injection block 151 to adjust an injection direction of the cooling gas CG injected from the first gas injection block 151.

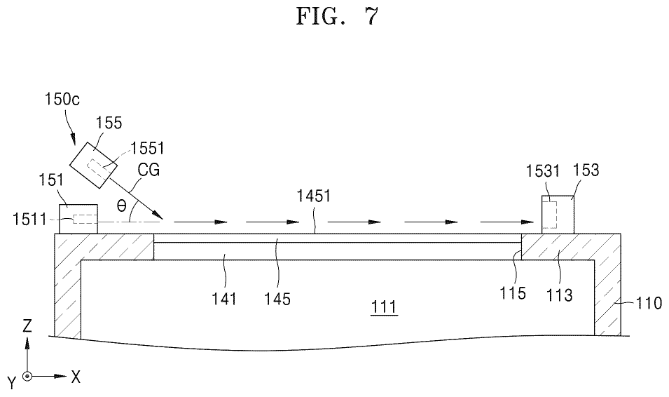

FIG. 7 is a configuration diagram showing a portion of a substrate processing apparatus including a cooling device 150c according to embodiments. Hereinafter, a substrate processing apparatus including the cooling device 150c of FIG. 5 is described, focusing on differences from the substrate processing apparatus 10 previously described with reference to FIGS. 1 to 4.

Referring to FIG. 7, the cooling device 150c may further include an additional gas injection block 155 disposed to face the first suction block 153 in a first direction (e.g., an X direction). The additional gas injection block 155 may be disposed near the first edge 145E1 of the transparent electrode 145 and may be disposed above the first gas injection block 151. The additional gas injection block 155 is configured to receive the cooling gas CG from the cooling gas supplier (152 in FIG. 1) and may include at least one injection port 1551 configured to inject the cooling gas CG.

The first gas injection block 151 and the additional gas injection block 155 may be configured to inject the cooling gas CG in different directions. In embodiments, the additional gas injection block 155 may be configured to inject the cooling gas CG in a direction parallel to the upper surface 1451 of the transparent electrode 145, and the additional gas injection block 155 may be configured to inject the cooling gas CG to the upper surface 1451 of the transparent electrode 145 in an inclined direction. In order to cool the transparent electrode 145, the first gas injection block 151 and the additional gas injection block 155 may simultaneously inject the cooling gas CG, and only one of the first gas injection block 151 and the additional gas injection block 155 may inject the cooling gas CG.

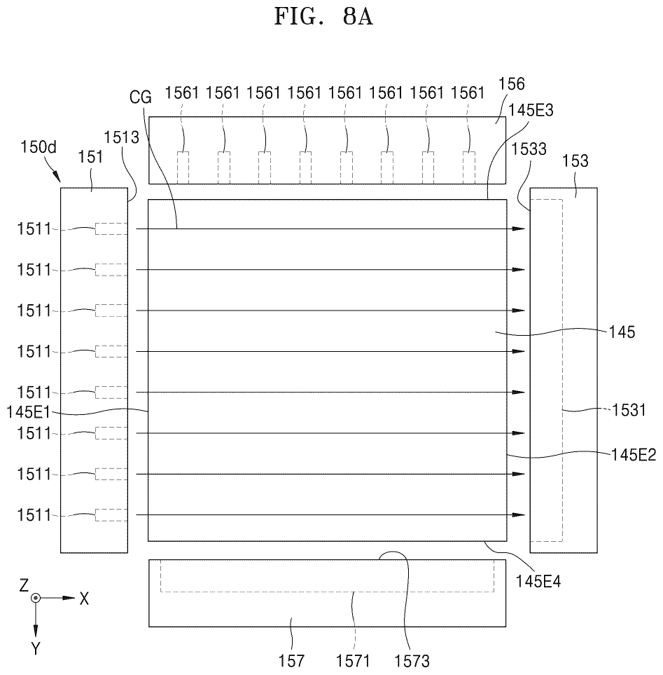

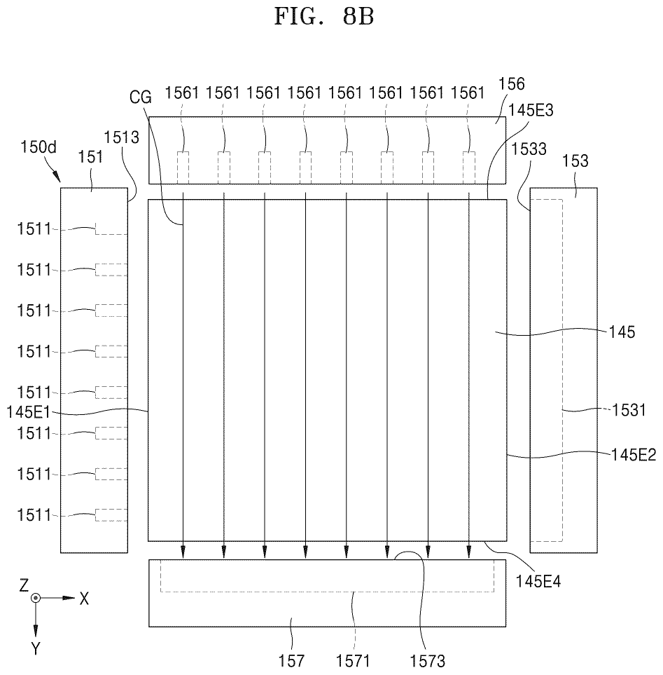

FIGS. 8A and 8B are configuration diagrams showing portions of a substrate processing apparatus 150d including a cooling device according to embodiments. Hereinafter, a substrate processing apparatus including a cooling device 150d of FIGS. 8A and 8B is described, focusing on differences from the substrate processing apparatus 10 previously described with reference to FIGS. 1 to 4.

Referring to FIGS. 8A and 8B together with FIG. 1, the cooling device 150d may further include a second gas injection block 156 and a second suction block 157 disposed to face each other in the second direction (e.g., a Y direction).

The second gas injection block 156 may be configured to receive a cooling gas CG from a cooling gas supplier 152 and inject the cooling gas CG toward the transparent electrode 145. The second gas injection block 156 may include at least one second injection port 1561 configured to inject the cooling gas CG. The injection surface 1563 of the second gas injection block 156 provided with the second injection port 1561 may be disposed to face the transparent electrode 145. The second gas injection block 156 may be disposed on an upper wall 113 of the chamber 110 and may be disposed so as not to overlap the transparent electrode 145 in a vertical direction (e.g., a Z direction). The second gas injection block 156 may be configured to inject the cooling gas CG in a direction parallel to the upper surface 1451 of the transparent electrode 145 and/or in an inclined direction with respect to the upper surface 1451 of the transparent electrode 145.

The second suction block 157 may be configured to suck the cooling gas CG injected from the second gas injection block 156. The second suction block 157 may include at least one second suction port 1571 configured to suck the cooling gas CG. The exhaust pump 154 may be connected to the second suction port 1571 through a suction line and may exhaust the cooling gas CG sucked into the second suction port 1571. The second suction block 157 may be disposed on the upper wall 113 of the chamber 110 and may be disposed so as not to overlap the transparent electrode 145 in a vertical direction (e.g., a Z direction).

In embodiments, the second gas injection block 156 and the second suction block 157 may be spaced apart from each other in the second direction (e.g., a Y direction) with the transparent electrode 145 therebetween, the second gas injection block 156 may be disposed near a third edge 145E3 of the transparent electrode 145, and the second suction block 157 may be disposed near a fourth edge 145E4 opposite to the third edge 145E3 of the transparent electrode 145. In this case, the injection surface 1563 or the second injection port 1561 of the second gas injection block 156 may face the suction surface 1573 or the second suction port 1571 of the second suction block 157 in the second direction (e.g., the Y direction). As the second gas injection block 156 and the second suction block 157 are disposed to face each other in the second direction (e.g., Y direction), an air flow of the cooling gas CG uniformly flowing in the second direction (e.g., the Y direction) along the upper surface 1451 of the transparent electrode 145 may be formed between the second gas injection block 156 and the second suction block 157.

In embodiments, the second gas injection block 156 and the second suction block 157 may have a bar shape extending in the first direction (e.g., an X direction). A length of the second gas injection block 156 along the first direction (e.g., the X direction) and a length of the second suction block 157 along the first direction (e.g., the X direction) may be equal to or greater than a length (or maximum width) of the transparent electrode 145 in the first direction (e.g., the X direction), respectively.

In embodiments, in order to cool the transparent electrode 145, only one of the first gas injection block 151 and the second gas injection block 156 may inject the cooling gas CG. For example, as shown in FIG. 8A, while the airflow of the cooling gas CG toward the first direction (e.g., X direction) is formed between the first gas injection block 151 and the first suction block 153 by the first gas injection block 151 injecting the cooling gas CG and the first suction block 153 sucking the cooling gas CG, an injecting of the cooling gas CG using the second gas injection block 156 and a sucking of the cooling gas CG using the second suction block 157 may be stopped. In addition, as shown in FIG. 8B, while the airflow of the cooling gas CG toward the second direction (e.g., Y direction) is formed between the second gas injection block 156 and the second suction block 157 by the second gas injection block 156 injecting the cooling gas CG and the second suction block 157 sucking the cooling gas CG, an injecting of the cooling gas CG using the first gas injection block 151 and a sucking of the cooling gas CG using the first suction block 153 may be stopped. In some embodiments, in order to cool the transparent electrode 145, the first gas injection block 151 and the second gas injection block 156 may simultaneously inject the cooling gas CG.

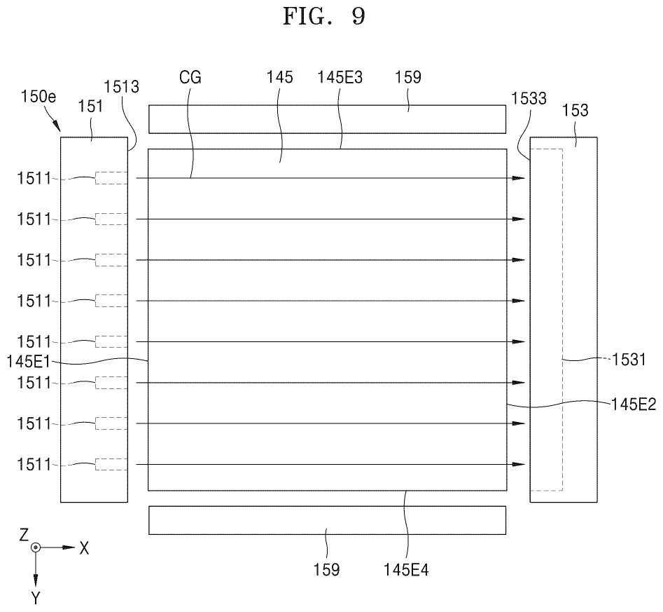

FIG. 9 is a configuration diagram showing a portion of a substrate processing apparatus including a cooling device 150e according to embodiments. Hereinafter, a substrate processing apparatus including the cooling device 150e of FIG. 9 is described, focusing on differences from the substrate processing apparatus 10 previously described with reference to FIGS. 1 to 4.

Referring to FIG. 9 together with FIG. 1, the cooling device 150e may include flow guide blocks 159. The flow guide blocks 159 may be disposed on the upper wall 113 of the chamber 110 and may be disposed so as not to overlap the transparent electrode 145 in a vertical direction. The flow guide blocks 159 may be spaced apart from each other in a second direction (e.g., Y direction) with the transparent electrode 145 therebetween. One of the flow guide blocks 159 may be disposed near the third edge 145E3 of the transparent electrode 145 and extends linearly from one end to the other end of the third edge 145E3, and another one of the flow guide blocks 159 may be disposed near the fourth edge 145E4 of the transparent electrode 145 and linearly extend from one end to the other end of the fourth edge 145E4.

The flow guide blocks 159 may be configured to guide the flow of the cooling gas CG formed by the first gas injection block 151 and the first suction block 153. That is, the flow guide blocks 159 may linearly extend in a first direction (e.g., X direction) between the first gas injection block 151 and the first suction block 153 to guide the flow of the cooling gas CG in the first direction (e.g., X direction). In addition, the flow guide blocks 159 may block the flow of the cooling gas CG in the second direction (e.g., Y direction) leaving the transparent electrode 145 to limit an area in which an airflow of the cooling gas CG is formed.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A substrate processing apparatus comprising:
a chamber including a processing space;
a support table provided within the processing space of the chamber and configured to support a substrate;
a dielectric plate covering an opening in an upper wall of the chamber;
a transparent electrode provided on the dielectric plate;
a laser supply head configured to supply a laser beam toward the substrate supported on the support table via the transparent electrode and the dielectric plate; and
a cooling device configured to cool the transparent electrode by injecting a cooling gas toward the transparent electrode.

2. The substrate processing apparatus of claim 1,
wherein the cooling device includes
a first gas injection block including at least one first injection ports configured to inject the cooling gas; and
a first suction block including at least one first suction port configured to suck the cooling gas, and disposed to face the first gas injection block in a first direction parallel to an upper surface of the transparent electrode.

3. The substrate processing apparatus of claim 2, wherein the first gas injection block is configured to inject the cooling gas in a direction parallel to the upper surface of the transparent electrode.

4. The substrate processing apparatus of claim 2,
wherein the first gas injection block is configured to inject the cooling gas in an inclined direction to the upper surface of the transparent electrode.

5. The substrate processing apparatus of claim 2, wherein the first gas injection block includes a plurality of first injection ports spaced apart from each other along a second direction parallel to the upper surface of the transparent electrode and perpendicular to the first direction.

6. The substrate processing apparatus of claim 5, wherein a length of the at least one first suction ports in the second direction is greater than a length of each of the plurality of first injection ports in the second direction.

7. The substrate processing apparatus of claim 2, wherein the cooling device is further configured to form an airflow of the cooling gas flowing in one direction along the upper surface of the transparent electrode between the first gas injection block and the first suction block.

8. The substrate processing apparatus of claim 7,
wherein the cooling device further includes
a second gas injection block including at least one second injection ports configured to inject the cooling gas; and
a second suction block including at least one second suction port configured to suck the cooling gas and disposed to face the second gas injection block in a second direction parallel to an upper surface of the transparent electrode and perpendicular to the first direction, and
the cooling device is configured to form an airflow of the cooling gas flowing in the second direction along the upper surface of the transparent electrode between the second gas injection block and the second suction block.

9. The substrate processing apparatus of claim 7, further comprising flow guide blocks spaced apart from each other in a second direction perpendicular to the first direction with the transparent electrode therebetween,
wherein the flow guide blocks extend in the first direction between the first gas injection block and the first suction block to guide the flow of the cooling gas in the first direction.

10. The substrate processing apparatus of claim 2,
further comprising an actuator configured to move the first gas injection block,
wherein the actuator is configured to move the first gas injection block to adjust an injection direction of the cooling gas injected from the first gas injection block.

11. The substrate processing apparatus of claim 2,
further comprising a third gas injection block spaced apart from the first suction block in the first direction with the transparent electrode therebetween,
wherein the first gas injection block is configured to inject the cooling gas in a direction parallel to an upper surface of the transparent electrode, and
the third gas injection block is configured to inject the cooling gas in an inclined direction to the upper surface of the transparent electrode.

12. The substrate processing apparatus of claim 1, wherein the dielectric plate includes quartz, and the transparent electrode includes indium tin oxide.

13. The substrate processing apparatus of claim 1, wherein the cooling gas includes at least one of clean dry air and nitrogen gas.

14. The substrate processing apparatus of claim 1, further comprising
a gas supplier configured to supply a process gas to the processing space;
a first power supply configured to supply first power to the transparent electrode; and
a second power supply configured to supply second power to an internal electrode plate of the support table.

15. A substrate processing apparatus comprising:
a chamber including a processing space;
a support table provided within the processing space of the chamber and configured to support a substrate;
a gas supplier configured to supply a process gas to the processing space;
a dielectric plate covering an opening in an upper wall of the chamber;
a transparent electrode provided outside the chamber and provided on the dielectric plate;
a first power supply configured to supply first power to the transparent electrode;
a second power supply configured to supply second power to an internal electrode plate of the support table;
a laser supply head configured to supply a laser beam toward the substrate on the support table through the transparent electrode and the dielectric plate; and
a cooling device configured to cool the transparent electrode by forming an airflow of a cooling gas flowing in one direction along an upper surface of the transparent electrode.

16. The substrate processing apparatus of claim 15,
wherein the cooling device includes
a first gas injection block including a plurality of first injection ports configured to inject the cooling gas; and
a first suction block including a first suction port configured to suck the cooling gas and spaced apart from the first gas injection block in a first direction from a first edge to a second edge of the transparent electrode,
wherein the plurality of first injection ports are spaced apart from each other in a second direction perpendicular to the first direction, and
the first suction port faces each of the plurality of first injection ports in the first direction.

17. The substrate processing apparatus of claim 16,
wherein the first gas injection block and the first suction block are spaced apart from each other in the first direction with the transparent electrode therebetween, and
a length of the first gas injection block in the second direction and a length of the suction block in the second direction are each greater than a length of the transparent electrode in the second direction.

18. The substrate processing apparatus of claim 16, wherein the first gas injection block and the first suction block are arranged so as not to overlap the transparent electrode in a vertical direction perpendicular to the upper surface of the transparent electrode.

19. The substrate processing apparatus of claim 16, wherein the cooling device is configured to supply the cooling gas toward the transparent electrode to cool the transparent electrode while the laser supply head supplies the laser beam toward the substrate.

20. A substrate processing apparatus comprising:
a chamber including a processing space in which plasma is generated;
a support table provided within the processing space of the chamber and configured to support a substrate;
a gas supplier configured to supply a process gas to the processing space;
a dielectric plate covering an opening in an upper wall of the chamber;
a transparent electrode provided outside the chamber and provided on the dielectric plate;
a first power supply configured to supply first power to the transparent electrode;
a second power supply configured to supply second power to an internal electrode plate of the support table;
a laser supply head configured to supply a laser beam toward the substrate on the support table through the transparent electrode and the dielectric plate; and
a cooling device including a first gas injection block having a plurality of first injection ports configured to inject a cooling gas toward the transparent electrode and a first suction block having a first suction port configured to suck the cooling gas, wherein the first gas injection block and the first suction block are spaced apart from each other in a first direction parallel to an upper surface of the transparent electrode with the transparent electrode therebetween,
wherein the first gas injection block is disposed near a first edge of the transparent electrode and extends from one end to the other end of the first edge of the transparent electrode,
the first suction block is disposed near a second edge opposite to the first edge of the transparent electrode and extends from one end to the other end of the second edge of the transparent electrode,
the first suction port faces each of the plurality of first injection ports in the first direction,
a length in a vertical direction perpendicular to the upper surface of the transparent electrode of the first suction port is greater than a length in a vertical direction of each of the plurality of first injection ports, and
the cooling device is configured to form an airflow of the cooling gas flowing in one direction along the upper surface of the transparent electrode between the first gas injection block and the first suction block.
